(19) United States
(12) Patent Application Publication
(10) Pub. No.: US 2010/0271110 A1
(43) Pub. Date: Oct. 28, 2010

(54) DEVICE FOR THE OPERATION OF ELECTRONIC CIRCUITS ON A HIGH-VOLTAGE POTENTIAL

(75) Inventor: Horst Schroeder, Hamburg (DE)

Correspondence Address: LEYDIG, VOIT AND MAYER, TWO PRUDENTIAL PLAZA, SUITE 4900, 180 NORTH STETSON AVENUE, CHICAGO, IL, 60601, US

(73) Assignee: YXLON INTERNATIONAL GMBH, Hamburg (DE)

(21) Appl. No.: 12/665,798

(22) PCT Filed: Jun. 12, 2008
(86) PCT No.: PCT/EP08/04730

§ 371 Date: Jul. 1, 2010

(30) Foreign Application Priority Data
Jun. 20, 2007 (DE) 10 2007 028 428.6

(51) Int. Cl. G11C 5/14

(52) U.S. Cl. 327/530

(57) ABSTRACT

A device for operating an electronic circuit at a high-voltage potential includes a diode array installed in a high-voltage line, wherein a current is configured to flow over the high-voltage line through the diode array. A voltage drop over the diode array is applied to the electronic circuit, which is configured to provide information ascertained on the high-voltage line. An evaluation unit connected to the electronic circuit via a galvanically separated transmission device receives the information from the electronic circuit.

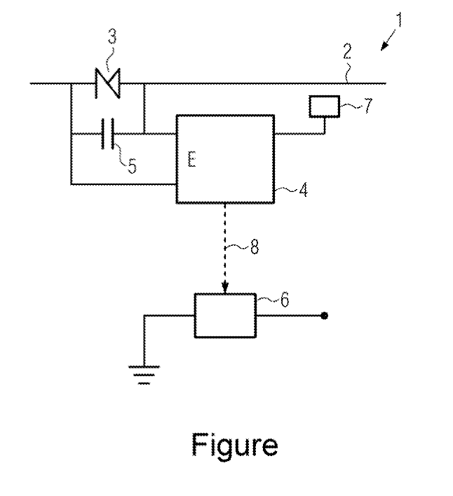

This is a U.S. National Phase Application under 35 U.S.C. §371 of International Application PCT/EP2008/004730, filed on Jun. 12, 2008, which claims priority to German Application No. DE 10 2007 028 428.6, filed on Jun. 20, 2007. The International Application was published in German on Dec. 24, 2008 as WO 2008/155065 under PCT Article 21 (2).

The present invention relates to a device for operating an electric/electronic circuit at high-voltage potential.

### BACKGROUND

It is sometimes necessary on lines to which a high voltage is applied to operate an electric/electronic circuit which must usually be operated in the low-voltage range. Such an electric circuit can be installed close to or directly against the high-voltage line and serve to record electric or non-electric values, for test purposes and the like. Such electronic circuits are usually operated at a supply voltage in the range from 2 to 15 V which cannot, however, directly be made available to the high-voltage line.

Solutions to date generate the supply voltage for operating the electronic circuit by means of a separate, galvanically separated voltage supply which is fed from the earth potential. This solution costs money and time.

### SUMMARY OF THE INVENTION

An aspect of the present invention is to provide a device which makes it possible to operate an electronic circuit with electrical energy which is transmitted over a high-voltage line, without leading to a costly additional supply voltage from the earth potential to the high-voltage potential.

According to one feature, a device is provided for operating an electronic circuit at a high-voltage potential. The device comprises a diode array which is installed in a high-voltage line such that a current flowing over the high-voltage line flows through the diode array. Furthermore, the electronic circuit is applied to the voltage dropping over the diode array and provides information ascertained on the high-voltage line. An evaluation unit is connected to the electronic circuit via a galvanically separated transmission device, in order to receive the ascertained information.

In an embodiment of the present invention a high-voltage line is attached to a diode array over which a near-constant voltage drops if an electric current flows in a specific current range on the high-voltage line. The voltage can be used to operate an electronic circuit which can be installed directly against the high-voltage line without needing to be galvanically separated from the latter. Only the transmission e.g. of measured values, test results and the like to the evaluation unit formed separated from same takes place via an interface which brings about a galvanic separation between the electronic circuit and the evaluation point.

According to an embodiment the diode array comprises a series connection of one or more diodes, in particular Zener diodes. Furthermore a capacitor can be connected parallel to the diode array. To produce a galvanic separation between the evaluation unit and the electronic circuit the transmission device can comprise an optical waveguide or a radio link.

The electronic circuit can have a temperature-recording circuit which is connected to a temperature detector. Furthermore, the evaluation unit can have an earth potential.

### BRIEF DESCRIPTION OF THE DRAWINGS

The sole FIGURE shows a block diagram of the device 1 for operating an electronic circuit 4 at high-voltage potential.

### DETAILED DESCRIPTION

The device 1 is installed against a high-voltage line 2. The high-voltage line 2 is designed to guide high-voltage potentials such as e.g. for currents over 1000 volts, preferably for currents at approx. 100 kvolts. By an electronic circuit 4 is meant in this description any apparatus which can be electrically operated.

For this, the high-voltage line 2 is provided with a diode array 3 which is installed in the high-voltage line 2. As soon as a small current flows on the high-voltage line 2, it thus also flows through the diode array 3, such that a specific current, the diode current, drops over the diode array 3. The voltage is tapped via corresponding connection points in front of and behind the diode array 3 and applied to an electronic circuit 4 installed against the high-voltage line 2 in order to operate same.

The diode array 3 can for example be formed from a diode chain with one or more conventional diodes, a series connection or one or more Zener diodes or similar. The represented embodiment is a Zener diode. The Zener diode is provided reverse-biased in the high-voltage line 2 such that, when the current flow flows on the high-voltage line 2, a Zener current drops as supply voltage for the electronic circuit 4. When a current flows on the high-voltage line 2 the current also flows through the diode array 3 and brings about a voltage drop which is provided as supply voltage for the electronic circuit 4 over the diode array 3.

In order to buffer voltage fluctuations at the electronic circuit 4 due to current fluctuations on the high-voltage line 2, a capacitor 5 which smoothes the voltage applied to the electronic circuit 4 can be provided parallel to the diode array 3. The electronic circuit 4 need not be galvanically separated from the high-voltage line 2, such that the circuit located therein is substantially on or near the high-voltage potential which lies against the high-voltage line 2. Then, only voltage differences of the level of the voltage dropping over the diode array 3 prevail in the electronic circuit 4. There must, in this case, be a galvanic separation between the electronic circuit 4 and the earth potential. However, this generally obtains through the galvanic separation between the high-voltage line 2 and the earth potential.

The electronic circuit 4 can for example be provided in order to ascertain operating values, such as e.g. a temperature of an array installed against the high-voltage line 2 with the help of a temperature detector 7 or itself ascertain this or measure the current flowing over the high-voltage line 2. The electronic circuit 4 then provides the corresponding measured values. Alternatively, the electronic circuit 4 can also comprise a test circuit which provides test values regarding the operation of arrays installed against the high-voltage line 2.

The measured values or the test values are transmitted to an evaluation point 6 which is operated essentially in the range of the mass or earth potential. The transmission takes place with the help of a transmission device 8 such that the electronic circuit 4 and the evaluation point 5 are galvanically separated from each other.

Possible devices for transmitting the measured values or test values between the electronic circuit 4 and the evaluation point 5 can for example be produced with the help of an optical waveguide or a radio transmission of the corresponding measured values or test values.

1-6. (canceled)

7. A device for operating an electronic circuit at a high-voltage potential comprising:
a diode array installed in a high-voltage line, wherein a current is configured to flow over the high-voltage line through the diode array;
an electronic circuit, wherein a voltage drop over the diode array is applied to the electronic circuit, and wherein the electronic circuit is configured to provide information ascertained on the high-voltage line,
a galvanically separated transmission device; and
an evaluation unit, wherein the transmission device connects the evaluation unit to the electronic circuit so as to allow the evaluation unit to receive the information from the electronic circuit.

8. The device as recited in claim 7, wherein the diode array includes a series connection of at least two diodes.

9. The device as recited in claim 8, wherein at least one of the at least two diodes is a Zener diode.

10. The device as recited in claim 7, further comprising a capacitor connected in parallel to the diode array.

11. The device as recited in claim 7, wherein the transmission device includes one of an optical waveguide and a radio link.

12. The device as recited in claim 7, further comprising a temperature detector and wherein the electronic circuit includes a temperature-recording circuit connected to the temperature detector.

13. The device as recited in claim 7, wherein the evaluation unit includes an earth potential.
